(19) United States
(12) Patent Application Publication
(10) Pub. No.: US 2013/0243967 A1
(43) Pub. Date: Sep. 19, 2013

(54) FTO THIN FILM PREPARATION USING MAGNETRON SPUTTERING DEPOSITION WITH PURE TIN TARGET

(71) Applicant: Cheng-Chung Lee, Pin-Cheng (TW)

(72) Inventor: Cheng-Chung Lee, Pin-Cheng (TW)

(73) Assignee: National Central University, Jhongli City (TW)

(21) Appl. No.: 13/419,419

(22) Filed: Mar. 13, 2012

(51) Int. Cl. C23C 14/14; C23C 14/02

(52) U.S. Cl. 427/534; 427/576

(57) ABSTRACT

A fluorine-doped tin oxide (FTO) film preparation method includes the step of using a high purity tin ingot in a magnetron sputtering deposition as a target material, the step of applying argon (Ar) as a working gas to generate plasma for removing impurities from the tin target in increasing the purity of the tin target, and the step of applying reactive gases containing F atoms (CF₄) and oxygen (O₂) for enabling tetrafluoromethane (CF₄) to be dissociated by the generated plasma into fluorine ions and excited fluorine atoms for deposition with tin ions from the tin target on a substrate to form a thin film of fluorine-doped tin oxide on the substrate.

### BACKGROUND OF THE INVENTION

1. Field of the Invention

The present invention relates to FTO (fluorine-doped tin oxide) film preparation technology and more particularly, to a method of preparing a fluorine-doped tin oxide film by employing magnetron sputtering deposition using high purity tin as a target material and tetrafluoromethane (CF₄) as a reactive gas.

2. Description of the Related Art

In recent years, application of photoelectric semiconductor has been rapidly developed. Many related studies have been continuously reported. Photoelectric semiconductors are intensively used in solar cells, flat panel displays, light-emitting diodes, optical waveguide components, and etc. In the application of photoelectric components transparent conductive glass is a key material. As the glass itself is not conductive, it is necessary to coat a layer of transparent electrode on the substrate. For the advantages of good thermal stability in oxidative environment, excellent chemical and mechanical properties, fluorine-doped tin oxide film is intensively used in solar cells, gas sensors and touch panels. Conventionally, chemical vapor deposition, spray pyrolysis deposition, thermal evaporation deposition, pulse laser deposition or magnetron sputtering deposition may be selectively for the formation of a fluorine-doped tin oxide film on a substrate. Among these techniques, magnetron sputtering deposition is suitable for mass production and accurate film thickness control under a room temperature environment. A fluorine-doped tin oxide film in this method can have a high density. Further, this method allows deposition of a fluorine-doped tin oxide film on a plastic substrate. During sputtering deposition, expensive fluorine-doped tin oxide compound is used as a target material. As the composition of the target material is fixed during deposition, the quality of the target material determines the quality of the fluorine-doped tin oxide film. If an inferior quality of target material is used, the quality of the deposited fluorine-doped tin oxide film will be relatively lowered.

### SUMMARY OF THE INVENTION

The present invention has been accomplished under the circumstances in view. It is the main object of the present invention to provide a fluorine-doped tin oxide film preparation method, which greatly reduces the preparation cost and increases the quality of fluorine-doped tin oxide film.

To achieve this and other objects of the present invention, a fluorine-doped tin oxide film is prepared by using a high purity tin ingot in a magnetron sputtering deposition as a target material, and then applying argon (Ar) as a working gas to generate plasma for removing impurities from the tin target in increasing the purity of the tin target, and then applying reactive gases including tetrafluoromethane (CF4) and oxygen (O2) for enabling tetrafluoromethane (CF4) to be deionized by the generated plasma into fluorine ions and excited fluorine atoms for deposition with tin ions from the tin target on a substrate to form a thin film of fluorine-doped tin oxide on the substrate.

### BRIEF DESCRIPTION OF THE DRAWINGS

FIG. 1 is a fluorine-doped tin oxide (FTO) film preparation flow chart in accordance with a first embodiment of the present invention.

FIG. 2 is a fluorine-doped tin oxide (FTO) film preparation flow chart in accordance with a second embodiment of the present invention.

### DETAILED DESCRIPTION OF THE PREFERRED EMBODIMENT

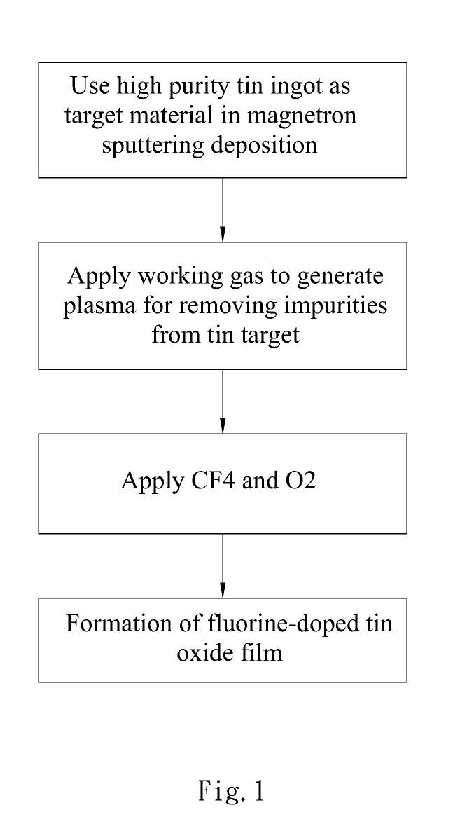

Referring to FIG. 1, a method for preparation of a fluorine-doped tin oxide (FTO) film in accordance with a first embodiment of the present invention includes the step of using a high purity tin ingot in a magnetron sputtering deposition as a target material, the step of delivering argon (Ar) as the working gas to generate plasma for removing impurities from the tin target to increase the purity of the tin target, the step of applying reactive gases tetrafluoromethane (CF₄) and oxygen (O₂) for enabling tetrafluoromethane (CF₄) to be deionized by the generated plasma into fluorine ions and excited fluorine atoms for deposition with tin ions from said tin target on a substrate to form a thin film of fluorine-doped tin oxide on said substrate.

The fluorine-doped tin oxide (FTO) film preparation method, comprising the steps of:

(a) using a high purity tin ingot in a magnetron sputtering deposition as a target material; and

(b) using inertia gas such as Ar as a working gas for enabling tetrafluoromethane (CF4) to be dissociated by the generated plasma into fluorine ions and excited fluorine atoms for deposition with tin ions from said tin target on a substrate to form a thin film of fluorine-doped tin oxide on said substrate;

wherein the applied reactive gases containing F atoms is selected from the group of CF4, C2F6, C4F10 NF3, and SF6; the oxygen (O2) is reactable with reactive gases containing F atoms to generate more F excited atoms and F ions in the presence of plasma during the sputtering deposition.

As the invention uses the relatively cheaper high purity tin ingot as a target material and high stability tetrafluoromethane (CF4) with oxygen (O2) as reactive gases for enabling fluorine ions that are dissociated from tetrafluoromethane (CF4) to react with tin oxide in forming a thin film of fluorine-doped tin oxide during sputtering deposition, the cost of the thin film of fluorine-doped tin oxide is minimized. Further, applying oxygen (O2) during sputtering deposition enhances fluorine deionization, and can react with carbon, which is deionized from tetrafluoromethane (CF4) during the presence of plasma, to form carbon dioxide (CO2) for exhaust, avoiding thin film or tin target contamination by carbon. Thus, the resistivity of the thin film thus made is greatly reduced and its visible light, short wave and near-UV penetration is greatly enhanced.

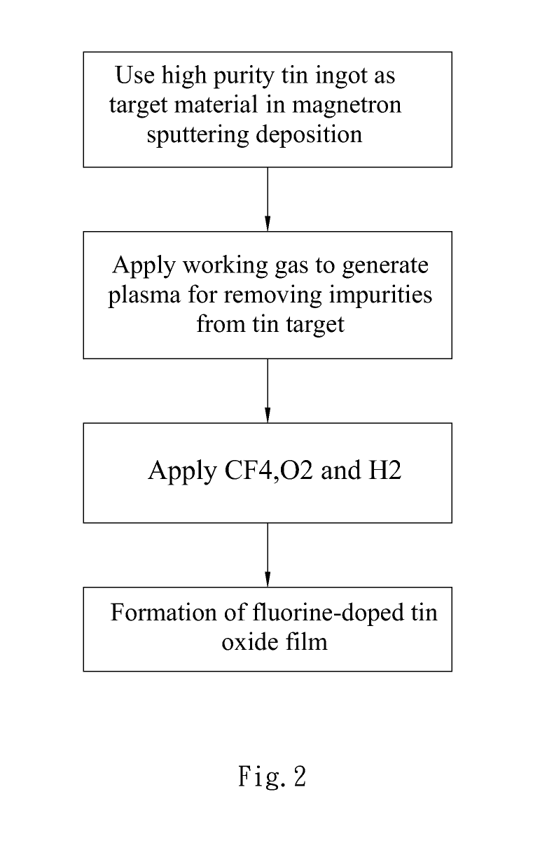

FIG. 2 is a fluorine-doped tin oxide (FTO) film preparation flow chart in accordance with a second embodiment of the present invention. This second embodiment is substantially similar to the aforesaid first embodiment with the exception that hydrogen (H₂) is added to the applied reactive gases tetrafluoromethane (CF₄) and oxygen (O₂), enhancing the conductivity of the thin film thus made and its visible light, short wave and near-UV penetration. The electrical and optical characteristics of the thin film thus made in a high temperature oxygen environment are highly stable. Subject to control of the ratio of the applied reactive gases and the reactive temperature during the preparation process, a high quality fluorine-doped tin oxide (FTO) film can be obtained.

Further, the substrate on which the fluorine-doped tin oxide (FTO) film is to be deposited can be an inorganic glass, quartz, fluorine or oxide board, or an organic flexible plastic board. Further, the magnetron sputtering deposition can be selected from the techniques of DC (direct current) magnetron sputtering deposition, RF (radio frequency) magnetron sputtering deposition, pulsed-DC magnetron sputtering deposition and high-power pulsed-DC magnetron sputtering deposition.

Although particular embodiments of the invention have been described in detail for purposes of illustration, various modifications and enhancements may be made without departing from the spirit and scope of the invention.

What the invention claimed is:

1. A fluorine-doped tin oxide (FTO) film preparation method, comprising the steps of:
(a) using a high purity tin ingot in a magnetron sputtering deposition as a target material; and
(b) using inertia gas such as Ar as a working gas for enabling tetrafluoromethane (CF₄) to be dissociated by the generated plasma into fluorine ions and excited fluorine atoms for deposition with tin ions from said tin target on a substrate to form a thin film of fluorine-doped tin oxide on said substrate;
wherein the applied reactive gases containing F atoms is selected from the group of CF₄, C₂F₆, C₄F₁₀NF₃, and SF₆; the oxygen (O₂) is reactable with reactive gases containing F atoms to generate more F excited atoms and F ions in the presence of plasma during the sputtering deposition.

2. The fluorine-doped tin oxide (FTO) film preparation method as claimed in claim 1, further comprising a sub step, after step (a) and before step (b), of applying argon (Ar) as a working gas to generate plasma for removing impurities from said tin target to increase the purity of said tin target.

3. The fluorine-doped tin oxide (FTO) film preparation method as claimed in claim 1, wherein the applied oxygen (O₂) reacts with carbon, which is dissociated from tetrafluoromethane (CF₄) in the presence of plasma during the sputtering deposition, to form carbon dioxide (CO₂) for exhaust.

4. The fluorine-doped tin oxide (FTO) film preparation method as claimed in claim 1, wherein the reactive gases applied during step (b) further include hydrogen for enhancing the conductivity and the visible light, short wave and near-UV penetration of the fluorine-doped tin oxide (FTO) film thus made.

5. The fluorine-doped tin oxide (FTO) film preparation method as claimed in claim 1, wherein said substrate is selected from the group of inorganic glass, quartz, fluorine and oxide boards and an organic flexible plastic board.

6. The fluorine-doped tin oxide (FTO) film preparation method as claimed in claim 1, wherein said magnetron sputtering deposition is DC (direct current) magnetron sputtering deposition.

7. The fluorine-doped tin oxide (FTO) film preparation method as claimed in claim 1, wherein said magnetron sputtering deposition is RF (radio frequency) magnetron sputtering deposition

8. The fluorine-doped tin oxide (FTO) film preparation method as claimed in claim 1, wherein said magnetron sputtering deposition is pulsed-DC magnetron sputtering deposition.

9. The fluorine-doped tin oxide (FTO) film preparation method as claimed in claim 1, wherein said magnetron sputtering deposition is high-power pulsed-DC magnetron sputtering deposition.
